(19) United States
(12) Patent Application Publication
(10) Pub. No.: US 2026/0311744 A1
(43) Pub. Date: Oct. 8, 2026

(54) MEMORY DEVICE INCLUDING BIT LINE SENSE AMPLIFIER AND OPERATING METHOD THEREOF

(71) Applicant: Samsung Electronics Co., Ltd., Suwon-si (KR)

(72) Inventors: Sang-Hoon JUNG, Suwon-si (KR); Younghun SEO, Suwon-si (KR); Hyun-Chul YOON, Suwon-si (KR); Chulwoo YI, Suwon-si (KR)

(73) Assignee: Samsung Electronics Co., Ltd., Suwon-si (KR)

(21) Appl. No.: 19/419,752

(22) Filed: Dec. 15, 2025

(30) Foreign Application Priority Data
Apr. 7, 2025 (KR) 10-2025-0044605

(51) Int. Cl. G11C 11/4091; G11C 11/4074; G11C 11/4076

(52) U.S. Cl. CPC G11C 11/4091; G11C 11/4074; G11C 11/4076

(57) ABSTRACT

A memory device that includes a bit line sense amplifier including a plurality of NMOS transistors and a plurality of PMOS transistors; and a power switch circuit that reduces a leakage current in the bit line sense amplifier by dynamically controlling one of a body voltage of the plurality of NMOS transistors and a body voltage of the plurality of PMOS transistors. The power switch circuit changes one of the body voltage of the plurality of NMOS transistors and the body voltage of the plurality of PMOS transistors from a first voltage to a second voltage, after the bit line sense amplifier performs an active operation; and changes the one of the body voltage of the plurality of NMOS transistors and the body voltage of the plurality of PMOS transistors from the second voltage to the first voltage, while the bit line sense amplifier performs a precharge operation.

### CROSS-REFERENCE TO RELATED APPLICATIONS

This application claims priority under 35 U.S.C. § 119 to Korean Patent Application No. 10-2025-0044605 filed on Apr. 7, 2025, in the Korean Intellectual Property Office, the disclosure of which is incorporated by reference herein in its entirety.

### BACKGROUND

The present disclosure relates to memory devices, and more particularly, relates to memory devices including a bit line sense amplifier and methods of operating thereof.

A semiconductor memory may be classified as a volatile memory device, in which stored data disappears when a power is turned off, such as a static random access memory (SRAM), a dynamic random access memory (DRAM), etc., and a nonvolatile memory device, in which stored data is retained even when a power is turned off, such as a flash memory devices, a phase-change RAM (PRAM), a magnetic RAM (MRAM), a resistive RAM (RRAM), a ferroelectric RAM (FRAM), etc.

A DRAM device includes memory cells connected with a word line and a bit line. Through the bit lines, the DRAM device stores data in memory cells or reads data stored in memory cells. The bit line sense amplifier may sense and amplify voltage changes of the bit lines of the DRAM device. As the DRAM device includes a large number of banks, a large number of the bit line sense amplifiers are also included.

Leakage current of transistors included in the bit line sense amplifier may increase due to a short channel effect for example, etc., due to a scaling down, and operation performance and/or operation reliability of the DRAM device may decrease.

### SUMMARY

Some example embodiments of the present disclosure provide a method of reducing a leakage current of a bit line sense amplifier.

Some example embodiments of the present disclosure provide a memory device that includes a bit line sense amplifier including a plurality of NMOS transistors and a plurality of PMOS transistors; and a power switch circuit that reduces a leakage current in the bit line sense amplifier by dynamically controlling one of a body voltage of the plurality of NMOS transistors and a body voltage of the plurality of PMOS transistors. The power switch circuit changes one of the body voltage of the plurality of NMOS transistors and the body voltage of the plurality of PMOS transistors from a first voltage to a second voltage, after the bit line sense amplifier performs an active operation; and changes the one of the body voltage of the plurality of NMOS transistors and the body voltage of the plurality of PMOS transistors from the second voltage to the first voltage, while the bit line sense amplifier performs a precharge operation.

Some example embodiments of the present disclosure further provide a method of operating a memory device including a bit line sense amplifier and a power switch circuit. The method includes the bit line sense amplifier performing an active operation; performing a leakage current reduction operation; and performing a precharge operation. The bit line sense amplifier includes a plurality of NMOS transistors and a plurality of PMOS transistors. The performing the leakage current reduction operation includes the power switch circuit reducing a leakage current in the bit line sense amplifier by dynamically controlling one of a body voltage of the plurality of NMOS transistors and a body voltage of the plurality of PMOS transistors.

Some example embodiments of the present disclosure still further provide a memory system that includes a memory controller including a power switch control circuit; and a memory device including a power switch circuit and a bit line sense amplifier. The bit line sense amplifier includes a plurality of NMOS transistors and a plurality of PMOS transistors. The power switch circuit reduces a leakage current in the bit line sense amplifier by dynamically controlling one of a body voltage of the plurality of NMOS transistors and a body voltage of the plurality of PMOS transistors based on a plurality of enable signals received from the power switch control circuit.

### BRIEF DESCRIPTION OF THE FIGURES

The above and other objects and features of the present disclosure will become apparent in view of the following detailed description of some example embodiments thereof with reference to the accompanying drawings.

FIG. 1 is a block diagram illustrating a memory system according to some example embodiments of the present disclosure.

FIG. 2 is a block diagram illustrating a memory device according to some example embodiments of the present disclosure.

FIG. 3 is a block diagram illustrating a sub array according to some example embodiments of the present disclosure.

FIG. 4 is a perspective view illustrating a stacked structure of a memory cell array according to some example embodiments of the present disclosure.

FIG. 5 is a circuit diagram illustrating a sub array according to some example embodiments of the present disclosure.

FIG. 6 is a timing diagram for describing operations of a bit line sense amplifier and a power switch circuit according to some example embodiments of the present disclosure.

FIG. 7 is a flowchart illustrating an operation of a memory device according to some example embodiments of the present disclosure.

FIG. 8 is a flowchart illustrating a leakage current reduction operation and a recovery operation of a memory device according to some example embodiments of the present disclosure.

FIG. 9 is a flowchart illustrating a precharge operation of a memory device according to some example embodiments of the present disclosure.

FIG. 10 is a flowchart illustrating an operation of a power switch circuit according to some example embodiments of the present disclosure.

FIG. 11 is a diagram illustrating a peripheral circuit layer according to some example embodiments of the present disclosure.

FIG. 12 is a diagram illustrating a system to which a memory device according to some example embodiments of the present disclosure is applied.

### DETAILED DESCRIPTION

Hereinafter, some example embodiments of the present disclosure will be described clearly and in detail such that those skilled in the art may easily understand carry out the inventive concepts.

In this specification, for example, the terms “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

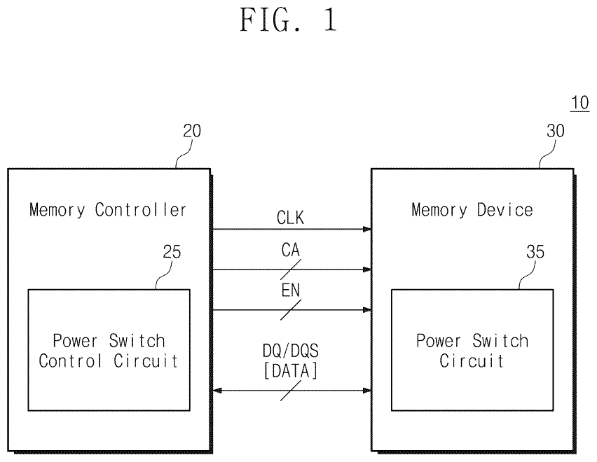

FIG. 1 is a block diagram illustrating a memory system according to some example embodiments of the present disclosure. Referring to FIG. 1, a memory system 10 may include a memory controller 20 and a memory device 30. In some example embodiments, the memory system 10 may be one of information processing devices configured to process various information and store the processed information, such as a personal computer, a laptop, a server, a workstation, a smartphone, a tablet PC, a digital camera, a black box, etc.

The memory controller 20 may store data in the memory device 30 or read data stored in the memory device 30. For example, the memory controller 20 may transmit a clock signal CLK and command/address signals CA to the memory device 30, and may exchange a data signal DQ and a data strobe signal DQS with the memory device 30. In some example embodiments, data may be transmitted from the memory controller 20 to the memory device 30, or transmitted from the memory device 30 to the memory controller 20, through the data signal and the data strobe signal. In some example embodiments, the memory controller 20 and the memory device 30 may communicate with each other based on a DDR interface, an LPDDR interface, etc., but the scope of the inventive concept is not limited thereto.

In some example embodiments, the memory controller 20 may include a power switch control circuit 25, and memory device 30 may include power switch circuit 35. The power switch control circuit 25 may transmit a plurality of enable signals EN to the power switch circuit 35. The power switch control circuit 25 may control operations of the power switch circuit 35 based on the plurality of enable signals EN.

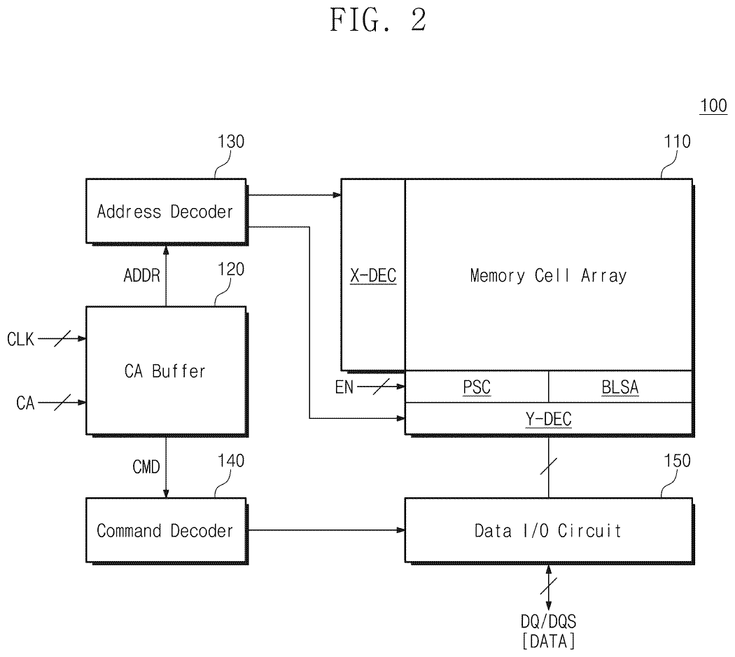

The power switch circuit 35 may provide various voltage levels to the bit line sense amplifier of the memory device 30 under control of the power switch control circuit 25. The power switch circuit 35 may provide various voltage levels to a bit line sense amplifier based on the received plurality of enable signals EN. The power switch circuit 35 may dynamically control various voltage levels provided to the bit line sense amplifier based on the received plurality of enable signals EN. The power switch circuit 35 may reduce a leakage current of the bit line sense amplifier, by dynamically controlling the voltage level provided to the bit line sense amplifier. Description of the operation of the power switch circuit 35 and the bit line sense amplifier will be described below with reference to FIGS. 2 to 10.

FIG. 2 is a block diagram illustrating a memory device according to some example embodiments of the present disclosure. Referring to FIG. 2, the memory device 100 may include a memory cell array 110, a command/address buffer 120, an address decoder 130, a command decoder 140, and a data I/O circuit 150. The memory device 100 of FIG. 2 may correspond to the memory device 30 of FIG. 1.

The memory cell array 110 may include a plurality of memory cells. The plurality of memory cells may be connected to word lines and bit lines, respectively. In some example embodiments, each of the plurality of memory cells may be a dynamic random access memory (DRAM) cell, but the scope of the inventive concepts is not limited thereto. For example, each of the plurality of memory cells may be implemented as any of a variety of types of the memory cells, such as PRAM, MRAM, RRAM, FRAM, TRAM, etc.

The memory cell array 110 may include a row decoder X-DEC, a column decoder Y-DEC, a power switch circuit PSC, and a bit line sense amplifier BLSA. The memory cell array 110 may be connected to the row decoder X-DEC through the plurality of word lines and connected to the column decoder Y-DEC through the plurality of bit lines. The row decoder X-DEC may control the plurality of word lines under control of the address decoder 130. The column decoder Y-DEC may control the plurality of bit lines according to the control of the address decoder 130. The power switch circuit PSC of FIG. 2 may correspond to the power switch circuit 35 of FIG. 1.

The bit line sense amplifier BLSA may read data of each of the plurality of memory cells, or write data to each of the plurality of memory cells. The bit line sense amplifier BLSA may be connected to the plurality of memory cells through bit lines. The bit line sense amplifier BLSA may sense and amplify voltage changes of bit lines. The amplified voltage changes may be output through the column decoder Y-DEC. The bit line sense amplifier BLSA may control voltages of bit lines controlled (or selected) by the column decoder Y-DEC.

The bit line sense amplifier BLSA may include a plurality of NMOS transistors and a plurality of PMOS transistors. During the bit line sense amplifier BLSA operating, a leakage current may flow through the bit line sense amplifier BLSA. For example, during the bit line sense amplifier BLSA operating, the leakage current may flow in the plurality of NMOS transistors or the plurality of PMOS transistors. For example, excessive power consumption due to the leakage current of the bit line sense amplifier BLSA occurs.

In some example embodiments, the power switch circuit PSC may reduce the leakage current by dynamically controlling one of a body voltage of the plurality of NMOS transistors and a body voltage of the plurality of PMOS transistors of the bit line sense amplifier BLSA. For example, the power switch circuit PSC may provide various voltage levels to one of the body node of the plurality of NMOS transistors and the body node of the plurality of PMOS transistors of the bit line sense amplifier BLSA under the control of the power switch control circuit 25 of FIG. 1 to reduce the leakage current.

After the bit line sense amplifier BLSA performs an active operation (e.g., in an active standby mode), the bit line sense amplifier BLSA may perform a leakage current reduction (LCR) operation. The active operation may be an operation of activating a word line and a bit line connected to the memory cell before the bit line sense amplifier BLSA performs a read/write operation on the memory cell. For example, the active operation may be an operation of activating the word line connected to the memory cell and amplifying the bit line connected to the memory cell to correspond to data stored in the memory cell before the bit line sense amplifier BLSA performs the read operation on the memory cell. In another example, the active operation may be an operation of activating the word line connected to the memory cell and amplifying the bit line connected to the memory cell to correspond to data received from the data I/O circuit 150 before the bit line sense amplifier BLSA performs the write operation on the memory cell. For example, the word line may be activated by the boost voltage VPP, and the bit line may be amplified by the power supply voltage VDD. Here, the boost voltage VPP may have a voltage level higher than the power supply voltage VDD. For example, after the bit line sense amplifier BLSA performs the active operation, the bit line sense amplifier may perform the leakage current reduction operation under the control of the power switch circuit PSC.

For example, when the power switch circuit PSC dynamically controls the body voltage of the plurality of NMOS transistors of the bit line sense amplifier BLSA, the power switch circuit PSC may provide a first voltage to the body node of the plurality of NMOS transistors while the bit line sense amplifier BLSA performs the active operation. Further, the power switch circuit PSC may provide a second voltage to the body node of the plurality of NMOS transistors, after the bit line sense amplifier BLSA performs the active operation. Here, the first voltage has a voltage level lower than a ground voltage, and the second voltage has a voltage level lower than the first voltage. For example, since the body voltage of the plurality of NMOS transistors decreases from the first voltage to the second voltage, the threshold voltage of the plurality of NMOS transistors may increase. Accordingly, the leakage current of the plurality of NMOS transistors may be reduced, thereby improving and/or increasing operation performance and/or operation reliability of memory device 30.

After the bit line sense amplifier BLSA performs the leakage current reduction operation (e.g., after the bit line sense amplifier performs the read/write operation), the bit line sense amplifier may perform a precharge operation. For example, during performing the precharge operation, the bit line sense amplifier BLSA may perform a recovery operation decreasing the increased threshold voltages of the plurality of NMOS transistors again under the control of the power switch circuit PSC.

For example, the power switch circuit PSC may provide a third voltage and then may provide the first voltage to the body node of the plurality of NMOS transistors, while the bit line sense amplifier BLSA performs the recovery operation. For example, the power switch circuit PSC may provide the third voltage for a desired (and/or alternatively predetermined) time and then may provide the first voltage to the body node of the plurality of NMOS transistors, while the bit line sense amplifier BLSA performs the recovery operation. Here, the third voltage has a voltage level equal to the ground voltage, or lower than the ground voltage and higher than the first voltage.

The body voltage of the plurality of NMOS transistors may increase from the second voltage to a voltage higher than the first voltage, while the third voltage is provided to the body node of the plurality of NMOS transistors. The body voltage of the plurality of NMOS transistors may decrease from the voltage higher than the first voltage to the first voltage, while the first voltage is provided to the body node of the plurality of NMOS transistors. Thus, the threshold voltage of the plurality of NMOS transistors may decrease again relatively compared to before performing the recovery operation. For example, the threshold voltage of the plurality of NMOS transistors after the bit line sense amplifier BLSA performs the recovery operation may be the same as the threshold voltage of the plurality of NMOS transistors while the bit line sense amplifier BLSA performs the active operation.

In another example, when the power switch circuit PSC dynamically controls the body voltage of the plurality of PMOS transistors of the bit line sense amplifier BLSA, the power switch circuit PSC may provide the first voltage to the body node of the plurality of PMOS transistors while the bit line sense amplifier BLSA performs the active operation. Further, the power switch circuit PSC may provide the second voltage to the body node of the plurality of PMOS transistors, after the bit line sense amplifier BLSA performs the active operation. Here, the first voltage has a voltage level higher than the boost voltage, and the second voltage has a voltage level higher than the first voltage. For example, since the body voltage of the plurality of PMOS transistors increases from the first voltage to the second voltage, the threshold voltages of the plurality of PMOS transistors may increase. Accordingly, the leakage current of the plurality of PMOS transistors may be reduced.

After the bit line sense amplifier BLSA performs the leakage current reduction operation (e.g., after the bit line sense amplifier performs the read/write operation), the bit line sense amplifier may perform the precharge operation. For example, during performing the precharge operation, the bit line sense amplifier BLSA may perform the recovery operation decreasing the increased threshold voltages of the plurality of PMOS transistors again under the control of the power switch circuit PSC.

For example, the power switch circuit PSC may provide the third voltage and then may provide the first voltage to the body node of the plurality of PMOS transistors, while the bit line sense amplifier BLSA performs the recovery operation. For example, the power switch circuit PSC may provide the third voltage for a desired (and/or alternatively predetermined) time and then may provide the first voltage to the body node of the plurality of PMOS transistors, while the bit line sense amplifier BLSA performs the recovery operation. Here, the third voltage has a voltage level equal to the boost voltage, or higher than the boost voltage and lower than the first voltage.

The body voltage of the plurality of PMOS transistors may decrease from the second voltage to a voltage lower than the first voltage, while the third voltage is provided to the body node of the plurality of PMOS transistors. The body voltage of the plurality of PMOS transistors may increase from the voltage lower than the first voltage to the first voltage, while the first voltage is provided to the body node of the plurality of PMOS transistors. Thus, the threshold voltage of the plurality of PMOS transistors may decrease again relative to before performing the recovery operation. For example, the threshold voltage of the plurality of PMOS transistors after the bit line sense amplifier BLSA performs the recovery operation may be the same as the threshold voltage of the plurality of PMOS transistors while the bit line sense amplifier BLSA performs the active operation.

Hereinafter, some example embodiments will be described with reference to an example where the power switch circuit PSC dynamically controls the body voltage of the plurality of NMOS transistors of the bit line sense amplifier BLSA in order to omit redundant description, but the scope of the inventive concepts is not limited thereto. The following description may be applied to some other example embodiments in which the power switch circuit PSC dynamically controls the body voltage of a plurality of PMOS transistors of a bit line sense amplifier BLSA in a somewhat similar manner, such as previously described with respect to the aforementioned another example.

The command/address buffer 120 may be configured to receive the command/address signals and the plurality of enable signals EN from an external device (e.g., the memory controller 20 of FIG. 1 or a registered clock driver (RCD)) through the command/address lines CA, and temporarily store or buffer the received signals.

The address decoder 130 may be configured to receive an address signal ADDR from the command/address buffer 120 and decode the received address signal ADDR. The address decoder 130 may be configured to control the row decoder X-DEC and the column decoder Y-DEC based on a decoding result.

The command decoder 140 may be configured to receive a command signal CMD from the command/address buffer 120 and decode the received command signal CMD. The command decoder 140 may control the components of the memory device 100 based on a decoding result. For example, when the command signal CMD received from the command/address buffer 120 is a write command, the command decoder 140 may control the operation of the data I/O circuit 150 such that the data DATA received through the data lines DQ/DQS and the data I/O circuit 150 is written to the memory cell array 110. Alternatively, when the command signal CMD received from the command/address buffer 120 is a read command, the command decoder 140 may control the operation of the data I/O circuit 150 such that the data DATA stored in the memory cell array 110 is read.

The data I/O circuit 150 may be configured to receive the data DATA from the external device (e.g., the memory controller 20 of FIG. 1) through the data lines DQ/DQS, or to transmit the data DATA to the external device. The data I/O circuit 150 may read the data DATA from the memory cell array 110 or write the data DATA to the memory cell array 110 under the control of the command decoder 140.

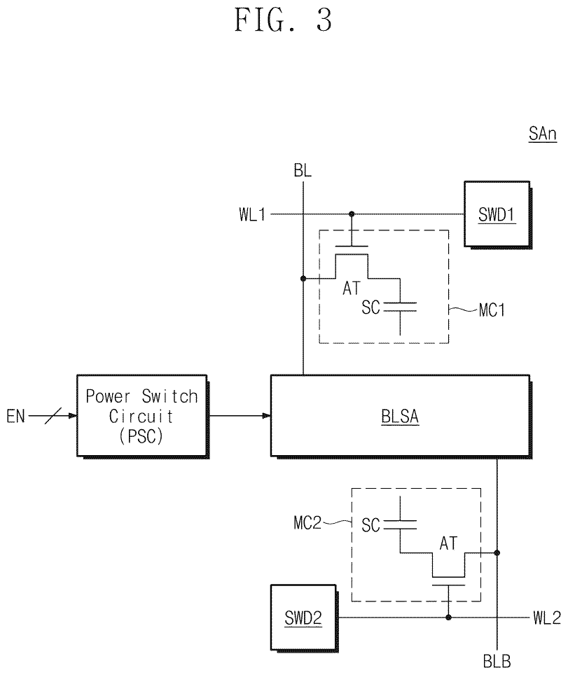

FIG. 3 is a block diagram illustrating a sub array according to some example embodiments of the present disclosure. Referring to FIGS. 2 and 3, the memory cell array 110 may include a plurality of sub arrays. For convenience of description, some example embodiments in which the memory cell array 110 includes an n-th sub array SAn is described with reference to FIG. 3, but the scope of the inventive concepts is not limited thereto. For example, the memory cell array 110 may further include additional sub arrays.

The n-th sub array SAn may include a power switch circuit PSC, a bit line sense amplifier BLSA, a first memory cell MC1, a first sub word line driver SWD1, a second memory cell MC2, and a second sub word line driver SWD2. In FIG. 3, for convenience of description, other components except the illustrated components are omitted, but the scope of the present disclosure is not limited thereto.

The first memory cell MC1 may be connected to a first word line WL1 and a first bit line BL, respectively. The first memory cell MC1 may be a DRAM cell. For example, the first memory cell MC1 may include an access transistor AT and a storage capacitor SC. The access transistor AT is connected between the first bit line BL and the storage capacitor SC, and may operate in response to a voltage level of the first word line WL1.

The first sub word line driver SWD1 may be configured to control the first word line WL1 connected to the first memory cell MC1. For example, the first sub word line driver SWD1 may be configured to control the first word line WL1 connected to the first memory cell MC1 under the control of the address decoder 130 (or the row decoder X-DEC).

The bit line sense amplifier BLSA may be connected to the first memory cell MC1 through the first bit line BL. As described above with reference to FIG. 2, the bit line sense amplifier BLSA may sense and amplify the voltage change of the first bit line BL.

The power switch circuit PSC may be connected to the bit line sense amplifier BLSA through the body node of the plurality of NMOS transistors of the bit line sense amplifier BLSA. As described above with reference to FIGS. 1 and 2, the power switch circuit PSC may dynamically control the body voltage of the plurality of NMOS transistors of the bit line sense amplifier BLSA to reduce the leakage current of the bit line sense amplifier BLSA.

The second memory cell MC2 is configured and operates in the same as the first memory cell MC1 except that the second memory cell MC2 is connected to the second word line WL2 and the second bit line BLB, respectively, and thus redundant description is omitted. Here, the second bit line BLB may be complementary to the first bit line BL. That is, the second bit line BLB may be a complementary bit line of the first bit line BL.

The second sub word line driver SWD2 is configured and operates in the same as the first sub word line driver SWD1 except that the second sub word line driver SWD2 is configured to control the second word line WL2 connected to the second memory cell MC2, and thus redundant description is omitted.

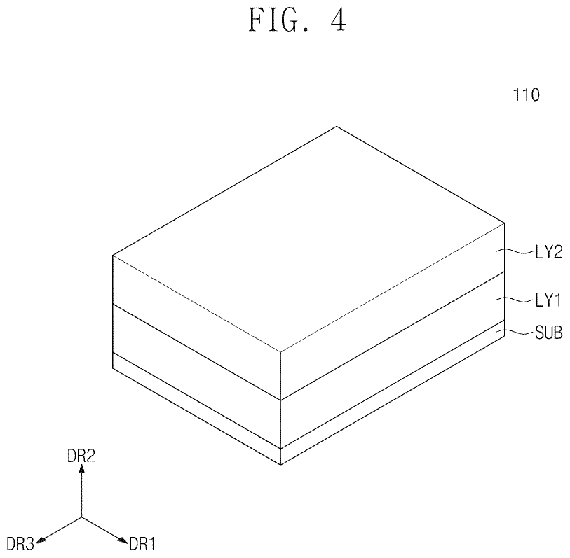

FIG. 4 is a perspective view illustrating a stacked structure of a memory cell array according to some example embodiments of the present disclosure. In some example embodiments, the memory cell array 110 of FIG. 2 may have the stacked structure. For example, as illustrated in FIG. 4, the memory cell array 110 may include a substrate SUB, a first layer LY1, and a second layer LY2.

The substrate SUB may be provided. The first layer LY1 may be formed on the substrate SUB. The first layer LY1 may include various elements (e.g., transistors) for implementing the first sub word line driver SWD1, the second sub word line driver SWD2, the bit line sense amplifier BLSA, and the power switch circuit PSC, as illustrated in FIG. 3.

The second layer LY2 may be formed on the first layer LY1. The second layer LY2 may include the first memory cell MC1 and the second memory cell MC2, as illustrated in FIG. 3. For example, the access transistor AT and the storage capacitor SC included in the plurality of memory cells may be formed in the second layer LY2.

As described above, the memory cell array 110 of the memory device 100 according to some example embodiments of the present disclosure may have the stacked structure or a Cell on Peripheral (CoP) structure in which the memory cells are formed on a peripheral circuit (e.g., the bit line sense amplifiers (BLSAs), the sub word line drivers (SWDs), the power switch circuits (PSCs), etc.).

In FIG. 4, the memory cell array 110 of the memory device 100 according to some example embodiments of the present disclosure is described as having the CoP structure in which the first layer LY1 (also referred to as a peripheral circuit layer) includes the peripheral circuit and the second layer LY2 (also referred as a memory cell layer) includes the memory cells, but the scope of the inventive concepts is not limited thereto. For example, the memory cell array 110 of the memory device 100 according to some example embodiments of the present disclosure may have a Peripheral on Cell (PoC) structure in which the first layer LY1 includes the memory cells and the second layer LY2 includes the peripheral circuit.

Hereinafter, for convenience of description, the memory cell array 110 according to some example embodiments of the present disclosure is described as having the CoP structure in which the first layer LY1 is the peripheral circuit layer and the second layer LY2 is the memory cell layer, but the scope of the inventive concepts is not limited thereto.

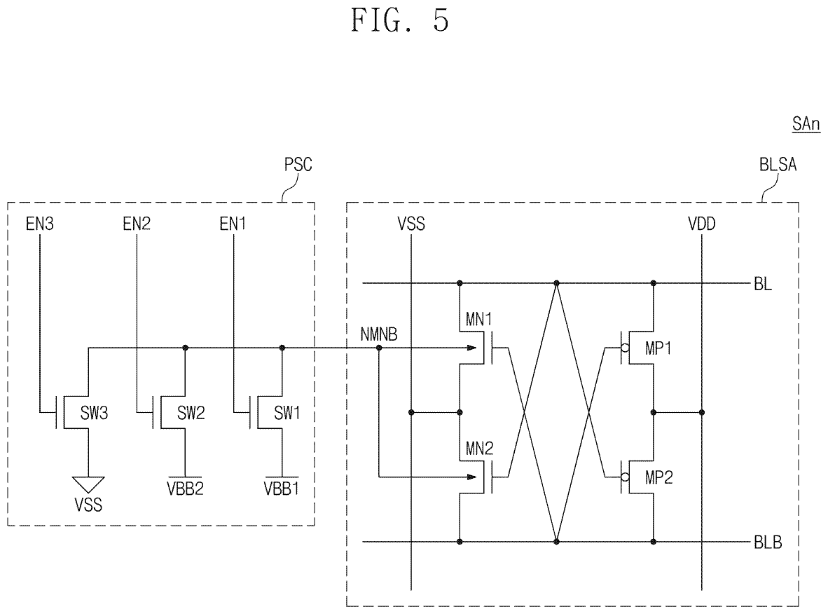

FIG. 5 is a circuit diagram illustrating a sub array according to some example embodiments of the present disclosure. For convenience of description, one bit line sense amplifier BLSA and one power switch circuit PSC are described, but the scope of the present disclosure is not limited thereto. For example, one sub array may include a plurality of bit line sense amplifiers BLSAs and a plurality of power switch circuits PSCs, and each of the plurality of bit line sense amplifiers BLSAs and each of the plurality of power switch circuits PSCs may have a structure similar or perform similar operations/functions to that of the bit line sense amplifier BLSA and the power switch circuit PSC described with reference to FIG. 5. Various control signals provided to each of the plurality of bit line sense amplifiers BLSAs and the plurality of power switch circuits PSCs may vary depending on the operation of the memory device 100.

Referring to FIGS. 1, 2, 3, and 5, the n-th sub array SAn may include a bit line sense amplifier BLSA and a power switch circuit PSC. The bit line sense amplifier BLSA may include a first PMOS transistor MP1, a first NMOS transistor MN1, a second PMOS transistor MP2, and a second NMOS transistor MN2. The first PMOS transistor MP1 and the first NMOS transistor MN1 may form a first CMOS inverter, and the second PMOS transistor MP2 and the second NMOS transistor MN2 may form a second CMOS inverter. The bit line sense amplifier BLSA may be configured such that an output of the first CMOS inverter is positively fed back to an input of the second CMOS inverter, and an output of the second CMOS inverter is positively fed back to an input of the first CMOS inverter. That is, the bit line sense amplifier BLSA may have a latch structure based on a cross-coupled inverter structure.

The power switch circuit PSC may be connected to the bit line sense amplifier BLSA through the body node NMNB of the plurality of NMOS transistors (or the body node N MNB of the NMOS transistor). The power switch circuit PSC may be configured to dynamically control a voltage provided to the body node NMNB of the plurality of NMOS transistors based on a first enable signal EN1, a second enable signal EN2, and a third enable signal EN3 received from the memory controller 20. The first enable signal EN1, the second enable signal EN2, and the third enable signal EN3 may be included in the plurality of enable signals EN. The power switch circuit PSC may include a first switch SW1 connected between a first power supply terminal and the body node of the NMOS transistor NMNB, and configured to operate in response to the first enable signal EN1, a second switch SW2 connected between a second power supply terminal and the body node of the NMOS transistor NMNB, and configured to operate in response to the second enable signal EN2, and a third switch SW3 connected between a third power supply terminal and the body node NMNB of the NMOS transistor, and configured to operate in response to the third enable signal EN3.

A first voltage VBB1 may be applied to the first power supply terminal, a second voltage VBB2 may be applied to the second power supply terminal, and a third voltage may be applied to the third power supply terminal. Hereinafter, for convenience of description, the third voltage is illustratively described as having a voltage level equal to a ground voltage VSS, but the scope of the present disclosure is not limited thereto. That is, the first switch SW1 may be configured to transmit the first voltage VBB1 to the body node NMNB of the plurality of NMOS transistors in response to the first enable signal EN1, the second switch SW2 may be configured to transmit the second voltage VBB2 to the body node NMNB of the plurality of NMOS transistors in response to the second enable signal EN2, and the third switch SW3 may be configured to transmit the ground voltage VSS to the body node NMNB of the plurality of NMOS transistors in response to the third enable signal EN3.

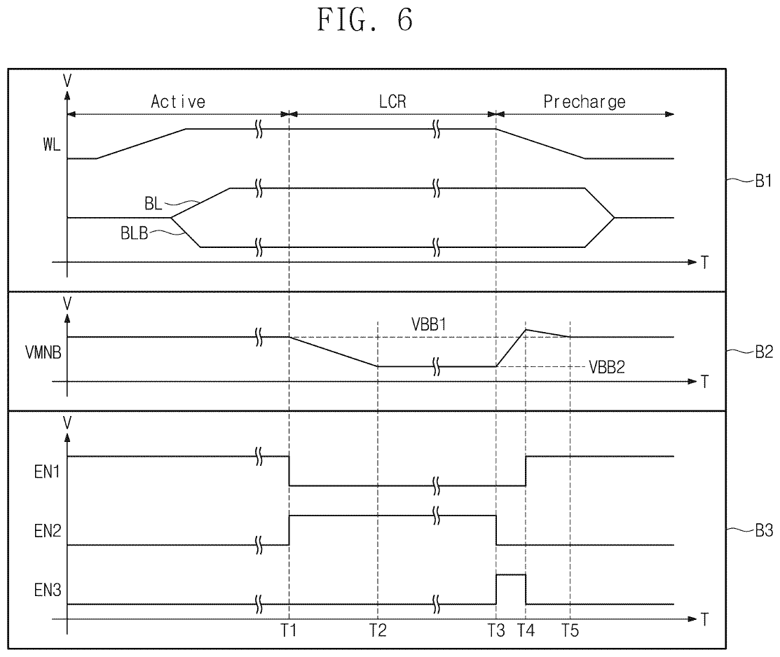

FIG. 6 is a timing diagram for describing operations of a bit line sense amplifier and a power switch circuit according to some example embodiments of the present disclosure. Referring to FIGS. 1, 2, 3, 5, and 6, a first box B1 illustrates the voltage levels of the first bit line BL, the second bit line BLB, and the word line WL connected to the memory cell on which the bit line sense amplifier BLSA is to perform the read/write operation, a second box B2 illustrates the body voltage VMNB of the plurality of NMOS transistors (or the body voltage VMNB of the NMOS transistor) of the bit line sense amplifier BLSA, and a third box B3 illustrates the voltage levels of the first enable signal EN1, the second enable signal EN2, and the third enable signal EN3 applied to the power switch circuit PSC. In the first box B1, the second box B2, and the third box B3, the horizontal axis represents the time T, and the vertical axis represents the voltage V.

In a period before a first time point T1, the bit line sense amplifier BLSA may perform th active operation. The first enable signal EN1 may be logic high, and the second enable signal EN2 and the third enable signal EN3 may be logic low. That is, the power switch circuit PSC may turn on the first switch SW1 based on the first enable signal EN1 of logic high, and turn off the second switch SW2 and the third switch SW3 based on the second enable signal EN2 and the third enable signal EN3 of logic low.

For example, the power switch circuit PSC may provide the first voltage VBB1 to the body node NMNB of the NMOS transistor of the bit line sense amplifier BLSA. Therefore, the body voltage VMNB of the NMOS transistor of the bit line sense amplifier BLSA may be the first voltage VBB1.

As the bit line sense amplifier BLSA performs the active operation, the word line WL may be activated, and the voltage levels of the first bit line BL and the second bit line BLB may be amplified by the bit line sense amplifier BLSA.

In a period between the first time point T1 and a third time point T3, the bit line sense amplifier BLSA may perform the leakage current reduction (LCR) operation. The first enable signal EN1 may be logic low, the second enable signal EN2 may be logic high, and the third enable signal EN3 may be logic low. That is, the power switch circuit PSC may turn off the first switch SW1 based on the first enable signal EN1 of logic low, turn on the second switch SW2 based on the second enable signal EN2 of logic high, and turn off the third switch SW3 based on the third enable signal EN3 of logic low.

For example, the power switch circuit PSC may provide the second voltage VBB2 to the body node NMNB of the NMOS transistor of the bit line sense amplifier BLSA. Therefore, in a period between the first time point T1 and a second time point T2, the body voltage VMNB of the NMOS transistor of the bit line sense amplifier BLSA may decrease from the first voltage VBB1 to the second voltage VBB2. In a period between the second time point T2 and the third time point T3, the body voltage VMNB of the NMOS transistor of the bit line sense amplifier BLSA may be the second voltage VBB2.

For example, the period between the first time point T1 and the third time point T3 may include a period during which the bit line sense amplifier BLSA is in the active standby mode. For example, the period between the first time point T1 and the third time point T3 may include a period during which the bit line sense amplifier BLSA performs the read/write operation on the memory cell.

In the period between the first time point T1 and the third time point T3, as described above, since the body voltage VMNB of the plurality of NMOS transistors decreases from the first voltage VBB1 to the second voltage VBB2, the threshold voltage of the plurality of NMOS transistors may increase. Accordingly, the power switch circuit PSC may reduce the leakage current flowing through the plurality of NMOS transistors of the bit line sense amplifier BLSA.

In the period between the first time point T1 and the third time point T3, the voltage levels of the first bit line BL and the second bit line BLB connected to the bit line sense amplifier BLSA may be already amplified, and the word line WL connected to the memory cell on which the bit line sense amplifier BLSA is to perform the read/write operation may be already activated. Therefore, even if the power switch circuit PSC dynamically controls the voltage provided to the body node NMNB of the plurality of NMOS transistors to reduce the leakage current, and the body voltage VMNB of the plurality of NMOS transistors is changed, the reliability of the read/write operation for the memory cell of the bit line sense amplifier BLSA may not be degraded.

In a period after the third time point T3, the bit line sense amplifier BLSA may perform the precharge operation. In a period between the third time point T3 and a fifth time point T5, the bit line sense amplifier BLSA may perform the recovery operation. For example, the bit line sense amplifier BLSA may perform the recovery operation during performing the precharge operation. For example, in a period between the third time point T3 and a fourth time point T4, the first enable signal EN1 and the second enable signal EN2 may be logic low, and the third enable signal EN3 may be logic high. That is, the power switch circuit PSC may turn off the first switch SW1 and the second switch SW2 based on the first enable signal EN1 and the second enable signal EN2 of logic low, and turn on the third switch SW3 based on the third enable signal EN3 of logic high.

For example, the power switch circuit PSC may provide the ground voltage VSS to the body node NMNB of the NMOS transistor of the bit line sense amplifier BLSA. Therefore, in the period between the third time point T3 and the fourth time point T4, the body voltage VMNB of the NMOS transistor of the bit line sense amplifier BLSA may increase from the second voltage VBB2 to the voltage higher than the first voltage VBB1.

In a period after the fourth time point T4, the first enable signal EN1 may be logic high, and the second enable signal EN2 and the third enable signal EN3 may be logic low. That is, the power switch circuit PSC may turn on the first switch SW1 based on the first enable signal EN1 of logic high, and turn off the second switch SW2 and the third switch SW3 based on the second enable signal EN2 and the third enable signal EN3 of logic low.

For example, the power switch circuit PSC may provide the first voltage VBB1 to the body node NMNB of the NMOS transistor of the bit line sense amplifier BLSA. Therefore, in a period between the fourth time point T4 and the fifth time point T5, the body voltage VMNB of the NMOS transistor of the bit line sense amplifier BLSA may decrease from the voltage higher than the first voltage VBB1 to the first voltage VBB1. In a period after the fifth time point T5, the body voltage VMNB of the NMOS transistor of the bit line sense amplifier BLSA may be the first voltage VBB1.

As described above, in the period between the third time point T3 and the fifth time point T5, the operation performed by the bit line sense amplifier BLSA may be the recovery operation. For example, in the period between the third time point T3 and the fifth time point T5, the bit line sense amplifier BLSA may perform the recovery operation changing the body voltage VMNB of the NMOS transistor of the bit line sense amplifier BLSA from the second voltage VBB2 to the first voltage VBB1 under the control of the power switch circuit PSC.

In the period after the third time point T3, as described above, since the body voltage VMNB of the plurality of NMOS transistors increases again from the second voltage VBB2 to the first voltage VBB1, the threshold voltage of the plurality of NMOS transistors may decrease again. Accordingly, the reliability of the subsequent read/write operation on the memory cell of the bit line sense amplifier BLSA may not be degraded.

As the bit line sense amplifier BLSA performs the precharge operation, the word line WL may be deactivated, and the voltage levels of the amplified first bit line BL and second bit line BLB may be equal to each other (e.g., a voltage level of VDD/2) by the bit line sense amplifier BLSA.

In some example embodiments, in the period between the third time point T3 and the fourth time point T4, as the power switch circuit PSC provides the ground voltage VSS (or the third voltage) to the body node NMNB of the plurality of NMOS transistors of the bit line sense amplifier BLSA, a time required for the recovery operation changing the body voltage VMNB of the plurality of NMOS transistors from the second voltage VBB2 to the first voltage VBB1 may be shortened. For example, the period between the third time point T3 and the fourth time point T4 may be shorter than the period between the first time point T1 and the second time point T2.

In another example, when the power switch circuit PSC does not provide the ground voltage to the body node NMNB of the plurality of NMOS transistors of the bit line sense amplifier BLSA while the bit line sense amplifier BLSA performs the recovery operation(e.g., when the power switch circuit PSC provides the first voltage to the body nodes NMNB of the plurality of NMOS transistors of the bit line sense amplifier BLSA in the period after the third time point T3), the time required for the recovery operation may be longer than the period between the third time point T3 and the fifth time point T5.

In some example embodiments, the period between the third time point T3 and the fourth time point T4 may be predetermined. For example, when the period between the third time point T3 and the fourth time point T4 is excessively long, the body voltage VMNB of the plurality of NMOS transistors at the fourth time point T4 may be excessively higher than the first voltage VBB1. Therefore, a time required to decrease the body voltage VMNB of the plurality of NMOS transistors from the voltage higher than the first voltage VBB1 to the first voltage VBB1 (e.g., a period between the fourth time point T4 and the fifth time point T5) may be excessively long.

In another example, when the period between the third time point T3 and the fourth time point T4 is excessively short, the body voltage VMNB of the plurality of NMOS transistors at the fourth time point T4 may be lower than the first voltage VBB1. Therefore, power consumed to further increase the body voltage VMNB of the plurality of NMOS transistors from a voltage lower than the first voltage VBB1 to the first voltage VBB1 may be excessively large.

Therefore, in some example embodiments, the period between the third time point T3 and the fourth time point T4 may be predetermined (e.g., set) in consideration of the time required to change the body voltage VMNB of the plurality of NMOS transistors from the second voltage VBB2 to the first voltage VBB1 and the efficiency of power consumed.

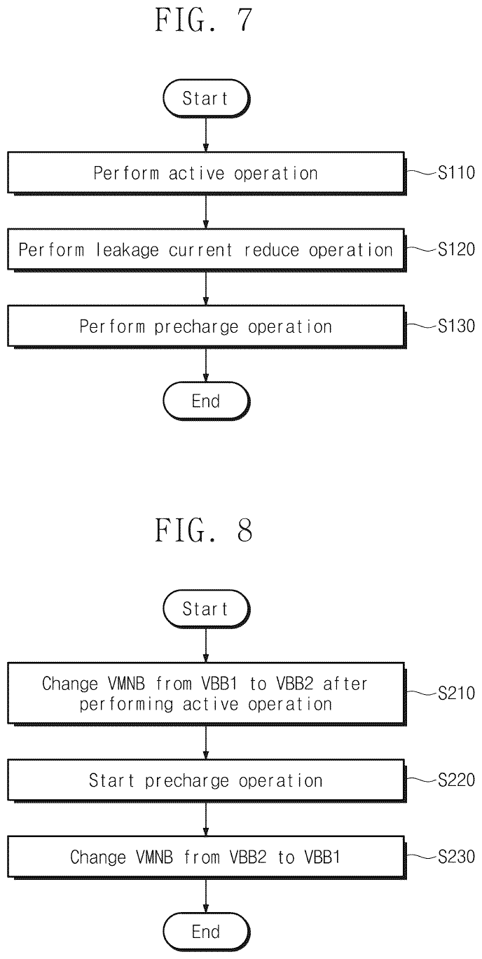

FIG. 7 is a flowchart illustrating an operation of a memory device according to some example embodiments of the present disclosure. Referring to FIGS. 1, 2, 3, 5, 6, and 7, in operation S110, the memory device 100 may perform the active operation. For example, the bit line sense amplifier BLSA of the memory device 100 may perform the active operation. Operation S110 may be the operation performed in the period before the first time point T1 of FIG. 6.

In operation S120, the memory device 100 may perform the leakage current reduction operation (LCR operation). For example, the bit line sense amplifier BLSA of the memory device 100 may perform the leakage current reduction operation. For example, the bit line sense amplifier BLSA of the memory device 100 may perform the leakage current reduction operation under the control of the power switch circuit PSC of the memory device 100. Operation S120 may be the operation performed in the period between the first time point T1 and the third time point T3 of FIG. 6.

In operation S130, the memory device 100 may perform the precharge operation. For example, the bit line sense amplifier BLSA of the memory device 100 may perform the precharge operation. For example, the bit line sense amplifier BLSA of the memory device 100 may perform the precharge operation under the control of the power switch circuit PSC of the memory device 100. Operation S130 may be the operation performed in the period after the third time point T3 of FIG. 6.

FIG. 8 is a flowchart illustrating a leakage current reduction operation and a recovery operation of a memory device according to some example embodiments of the present disclosure. Referring to FIGS. 1, 2, 3, 5, 6, 7, and 8, in operation S210, after performing the active operation, the memory device 100 may change the body voltage VMNB of the plurality of NMOS transistors of the bit line sense amplifier BLSA from the first voltage VBB1 to the second voltage VBB2. For example, the power switch circuit PSC of the memory device 100 may change the body voltage VMNB of the plurality of NMOS transistors of the bit line sense amplifier BLSA from the first voltage VBB1 to the second voltage VBB2, after the bit line sense amplifier BLSA of the memory device 100 performs the active operation. Operation S210 may be the leakage current reduction operation performed in the period between the first time point T1 and the third time point T3 of FIG. 6.

In operation S220, the memory device 100 may start the precharge operation. For example, the bit line sense amplifier BLSA of the memory device 100 may start the precharge operation. Operation S220 may be the operation performed at the third time point T3 of FIG. 6.

In operation S230, the memory device 100 may change the body voltage VMNB of the plurality of NMOS transistors of the bit line sense amplifier BLSA from the second voltage VBB2 to the first voltage VBB1. For example, the memory device 100 may change the body voltage VMNB of the plurality of NMOS transistors of the bit line sense amplifier BLSA from the second voltage VBB2 to the first voltage VBB1 while the bit line sense amplifier BLSA performs the precharge operation. For example, the power switch circuit PSC of the memory device 100 may change the body voltage VMNB of the plurality of NMOS transistors of the bit line sense amplifier BLSA from the second voltage VBB2 to the first voltage VBB1. Operation S230 may be the recovery operation performed in the period between the third time point T3 and the fifth time point T5 of FIG. 6.

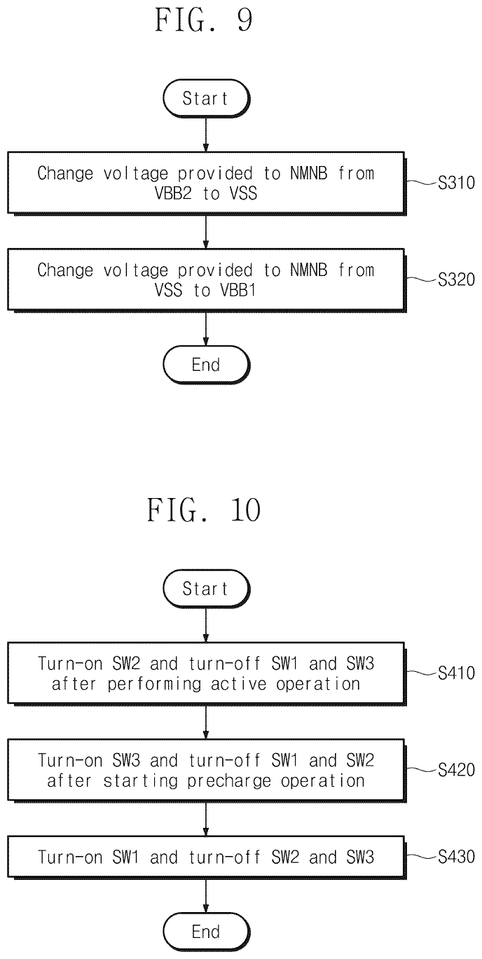

FIG. 9 is a flowchart illustrating a precharge operation of a memory device according to some example embodiments of the present disclosure. Referring to FIGS. 1, 2, 3, 5, 6, 7, 8, and 9, in operation S310, the memory device 100 may change the voltage provided to the body node NMNB of the plurality of NMOS transistors of the bit line sense amplifier BLSA from the second voltage VBB2 to the ground voltage VSS (or the third voltage). For example, the power switch circuit PSC of the memory device 100 may change the voltage provided to the body node NMNB of the plurality of NMOS transistors of the bit line sense amplifier BLSA from the second voltage VBB2 to the ground voltage VSS. Operation S310 may be the operation performed in the period between the third time point T3 and the fourth time point T4 of FIG. 6.

In operation S320, the memory device 100 may change the voltage provided to the body node NMNB of the plurality of NMOS transistors of the bit line sense amplifier BLSA from the ground voltage VSS to the first voltage VBB1. For example, the power switch circuit PSC of the memory device 100 may provide the ground voltage VSS to the body node NMNB of the plurality of NMOS transistors of the bit line sense amplifier BLSA for the desired (and/or alternatively predetermined) time, and then may change the voltage provided to the body node NMNB of the plurality of NMOS transistors of the bit line sense amplifier BLSA from the ground voltage VSS to the first voltage VBB1. Operation S320 may be the operation performed in the period after the fourth time point T4 of FIG. 6.

FIG. 10 is a flowchart illustrating an operation of a power switch circuit according to some example embodiments of the present disclosure. Referring to FIGS. 1, 2, 3, 5, 6, 7, 8, 9, and 10, in operation S410, the power switch circuit PSC may turn on the second switch SW2 and turn off the first switch SW1 and the third switch SW3 after the bit line sense amplifier BLSA performs the active operation. For example, the power switch circuit PSC may turn on the second switch SW2 and turn off the first switch SW1 and the third switch SW3 based on the plurality of enable signals EN1, EN2, and EN3 received from the power switch control circuit 25 of FIG. 1 after the bit line sense amplifier BLSA performs the active operation. Operation S410 may be the operation performed at the first time point T1 of FIG. 6.

In operation S420, the power switch circuit PSC may turn on the third switch SW3 and turn off the first switch SW1 and the second switch SW2 after the bit line sense amplifier BLSA starts the precharge operation. For example, the power switch circuit PSC may turn on the third switch SW3 and turn off the first switch SW1 and the second switch SW2 based on the plurality of enable signals EN1, EN2, and EN3 received from the power switch control circuit 25 of FIG. 1 after the bit line sense amplifier BLSA starts the precharge operation. For example, the power switch circuit PSC may turn on the third switch SW3 and turn off the first switch SW1 and the second switch SW2 for the desired (and/or alternatively predetermined) time after the bit line sense amplifier BLSA starts the precharge operation. Operation S420 may be the operation performed in the period between the third time point T3 and the fourth time point T4 of FIG. 6.

In operation S430, the power switch circuit PSC may turn on the first switch SW1 and turn off the second switch SW2 and the third switch SW3. For example, the power switch circuit PSC may turn on the first switch SW1 and turn off the second switch SW2 and the third switch SW3 based on the plurality of enable signals EN1, EN2, and EN3 received from the power switch control circuit 25 of FIG. 1. Operation S430 may be the operation performed in the period after the fourth time point T4 of FIG. 6.

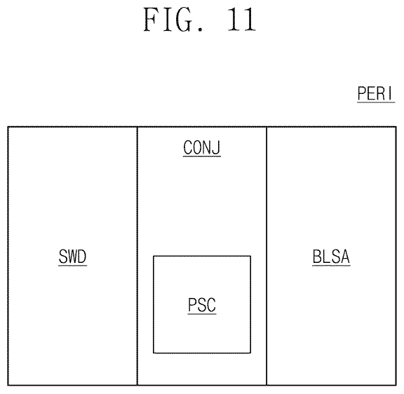

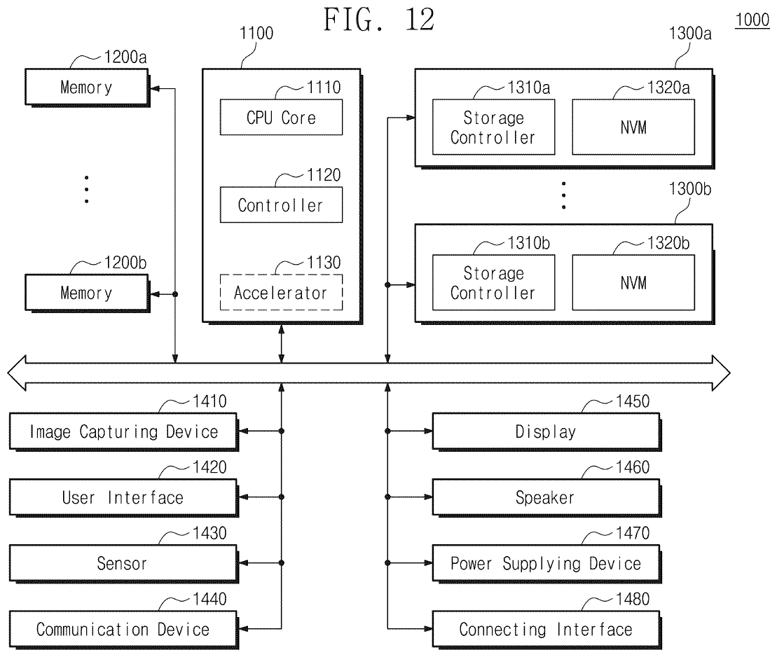

FIG. 11 is a diagram illustrating a peripheral circuit layer according to some example embodiments of the present disclosure. Referring to FIGS. 1, 2, 3, 4, 5, and 11, the peripheral circuit layer PERI may include the sub word line driver SWD, the bit line sense amplifier BLSA, and the conjunction region CONJ. For example, FIG. 11 may represent a region of the peripheral circuit layer PERI corresponding to one sub array.

For convenience of description, the peripheral circuit layer PERI is illustrated to include one sub word line driver SWD and one bit line sense amplifier BLSA, but the scope of the present disclosure is not limited thereto. For example, the peripheral circuit layer PERI may include various components to control/support operations of the memory cell array 110, such as the plurality of sub word line drivers (SWDs), the plurality of bit line sense amplifiers (BLSAs), the row decoder (X-DEC), and the column decoder (Y-DEC).

The conjunction region CONJ may be a region other than a region in which the sub word line driver SWD and the bit line sense amplifier BLSA are embedded in the peripheral circuit layer PERI. For example, the conjunction region CONJ may be a region between the region in which the sub word line driver SWD is embedded and the region in which the bit line sense amplifier BLSA is embedded in the peripheral circuit layer PERI.

The conjunction region CONJ may include the power switch circuit PSC. For example, the conjunction region CONJ may further include various components to control/support operations of the memory cell array 110, such as the row decoder X-DEC, the column decoder Y-DEC, etc. For example, the power switch circuit PSC may be embedded in the conjunction region CONJ. For example, as the memory cell array 110 according to some example embodiments of the present disclosure has the CoP structure or the PoC structure, there may be an empty region (or a spare region) in which the power switch circuit PSC is to be embedded in the conjunction region CONJ of the peripheral circuit layer PERI. Accordingly, the power switch circuit PSC may be embedded by utilizing the conjunction region CONJ without an additional increase in an area of the peripheral circuit layer PERI. That is, by embedding the power switch circuit PSC in the conjunction region CONJ, it is possible to reduce the leakage current of the bit line sense amplifier BLSA without an additional increase in a chip size.

FIG. 12 is a diagram illustrating a system to which a memory device according to some example embodiments of the present disclosure is applied. The system 1000 of FIG. 12 may basically be a mobile system, such as a portable communication terminal (e.g., a mobile phone), a smartphone, a tablet personal computer (PC), a wearable device, a healthcare device, or an Internet of things (IOT) device. However, the system 1000 of FIG. 12 is not necessarily limited to the mobile system and may be a PC, a laptop computer, a server, a media player, or an automotive device (e.g., a navigation device).

Referring to FIG. 12, the system 1000 may include a main processor 1100, memories (e.g., 1200a and 1200b), and storage devices (e.g., 1300a and 1300b). The system 1000 may include at least one of an image capturing device 1410, a user input device 1420, a sensor 1430, a communication device 1440, a display 1450, a speaker 1460, a power supplying device 1470, and a connecting interface 1480.

The main processor 1100 may control all operations of the system 1000, for example, operations of other components included in the system 1000. The main processor 1100 may be implemented as a general-purpose processor, a dedicated processor, or an application processor.

The main processor 1100 may include at least one CPU core 1110 and further include a controller 1120 configured to control the memories 1200a and 1200b and/or the storage devices 1300a and 1300b. In some example embodiments, the main processor 1100 may further include an accelerator 1130, which is a dedicated circuit for a high-speed data operation, such as an artificial intelligence (AI) data operation. The accelerator 1130 may include a graphics processing unit (GPU), a neural processing unit (NPU) and/or a data processing unit (DPU) and be implemented as a chip that is physically separate from the other components of the main processor 1100.

The memories 1200a and 1200b may be used as main memory devices of the system 1000. Although each of the memories 1200a and 1200b may include a volatile memory, such as static random access memory (SRAM) and/or dynamic RAM (DRAM), each of the memories 1200a and 1200b may include non-volatile memory, such as a flash memory, phase-change RAM (PRAM) and/or resistive RAM (RRAM). The memories 1200a and 1200b may be implemented in the same package as the main processor 1100.

The storage devices 1300a and 1300b may serve as non-volatile storage devices configured to store data regardless of whether power is supplied thereto, and have larger storage capacity than the memories 1200a and 1200b. The storage devices 1300a and 1300b may respectively include storage controllers (STRG CTRL) 1310a and 1310b and NVM (Non-Volatile Memories) 1320a and 1320b configured to store data via the control of the storage controllers 1310a and 1310b. Although the NVMs 1320a and 1320b may include flash memories having a two-dimensional (2D) structure or a three-dimensional (3D) V-NAND structure, the NVMs 1320a and 1320b may include other types of NVMs, such as PRAM and/or RRAM.

The storage devices 1300a and 1300b may be physically separated from the main processor 1100 and included in the system 1000 or implemented in the same package as the main processor 1100. The storage devices 1300a and 1300b may have types of solid-state devices (SSDs) or memory cards and be removably combined with other components of the system 100 through an interface, such as the connecting interface 1480 that will be described below. The storage devices 1300a and 1300b may be devices to which a standard protocol, such as a universal flash storage (UFS), an embedded multi-media card (eMMC), or a non-volatile memory express (NVMe), is applied, without being limited thereto.

The image capturing device 1410 may capture still images or moving images. The image capturing device 1410 may include a camera, a camcorder, and/or a webcam.

The user input device 1420 may receive various types of data input by a user of the system 1000 and include a touch pad, a keypad, a keyboard, a mouse, and/or a microphone.

The sensor 1430 may detect various types of physical quantities, which may be obtained from the outside of the system 1000, and convert the detected physical quantities into electric signals. The sensor 1430 may include a temperature sensor, a pressure sensor, an illuminance sensor, a position sensor, an acceleration sensor, a biosensor, and/or a gyroscope sensor.

The communication device 1440 may transmit and receive signals between other devices outside the system 1000 according to various communication protocols. The communication device 1440 may include an antenna, a transceiver, and/or a modem.

The display 1450 and the speaker 1460 may serve as output devices configured to respectively output visual information and auditory information to the user of the system 1000.

The power supplying device 1470 may appropriately convert power supplied from a battery (not shown) embedded in the system 1000 and/or an external power source, and supply the converted power to each of components of the system 1000.

The connecting interface 1480 may provide connection between the system 1000 and an external device, which is connected to the system 1000 and capable of transmitting and receiving data to and from the system 1000. The connecting interface 1480 may be implemented by using various interface schemes, such as advanced technology attachment (ATA), serial ATA (SATA), external SATA (e-SATA), small computer small interface (SCSI), serial attached SCSI (SAS), peripheral component interconnection (PCI), PCI express (PCIe), NVMe, IEEE 1394, a universal serial bus (USB) interface, a secure digital (SD) card interface, a multi-media card (MMC) interface, an eMMC interface, a UFS interface, an embedded UFS (eUFS) interface, and a compact flash (CF) card interface.

In some example embodiments, the memory 1200a, 1200b of FIG. 12 may be the memory device (30 of FIG. 1 or 100 of FIG. 2) that includes a power switch circuit PSC that dynamically controls the voltage provided to the body node NMNB of the plurality of NMOS transistors of the bit line sense amplifier BLSA to reduce the leakage current flowing through the plurality of NMOS transistors of bit line sense amplifiers BLSA described with reference to FIGS. 1-11.

One or more of the elements disclosed above may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, an application-specific integrated circuit (ASIC), etc.

The above descriptions cover some example embodiments for carrying out the inventive concepts. Some example embodiments in which a design is simply changed or which are easily changed may be included in the present disclosure as well as some example embodiments described above. Technologies that are easily changed and implemented by using the above some example embodiments may be included in the present disclosure. Therefore, the scope of the present disclosure should not be limited to the above-described some example embodiments, and should be defined by not only the claims set forth, but also those equivalent to the claims of the present disclosure.

What is claimed is:

1. A memory device comprising:
a bit line sense amplifier comprising a plurality of NMOS transistors and a plurality of PMOS transistors; and
a power switch circuit configured to reduce a leakage current in the bit line sense amplifier by dynamically controlling one of a body voltage of the plurality of NMOS transistors and a body voltage of the plurality of PMOS transistors,
wherein the power switch circuit is configured to
change one of the body voltage of the plurality of NMOS transistors and the body voltage of the plurality of PMOS transistors from a first voltage to a second voltage, after the bit line sense amplifier performs an active operation, and
change the one of the body voltage of the plurality of NMOS transistors and the body voltage of the plurality of PMOS transistors from the second voltage to the first voltage, while the bit line sense amplifier performs a precharge operation.

2. The memory device of claim 1, further comprising a sub word line driver,
wherein the bit line sense amplifier, the power switch circuit, and the sub word line driver are included in a peripheral circuit layer, and
wherein the power switch circuit is included in a conjunction region between the bit line sense amplifier and the sub word line driver.

3. The memory device of claim 1, wherein the power switch circuit is configured to dynamically control the body voltage of the plurality of NMOS transistors by providing the first voltage having a first voltage level lower than a ground voltage, and the second voltage having a second voltage level lower than the first voltage.

4. The memory device of claim 3, wherein the power switch circuit is configured to dynamically control the body voltage of the plurality of NMOS transistors by providing one of the first voltage, the second voltage, and a third voltage to a body node of the plurality of NMOS transistors, and
wherein the third voltage has a third voltage level equal to the ground voltage, or lower than the ground voltage and higher than the first voltage.

5. The memory device of claim 4, wherein the power switch circuit comprises:
a first switch configured to provide the first voltage to the body node of the plurality of NMOS transistors, in response to a first enable signal;
a second switch configured to provide the second voltage to the body node of the plurality of NMOS transistors, in response to a second enable signal; and
a third switch configured to provide the third voltage to the body node of the plurality of NMOS transistors, in response to a third enable signal.

6. The memory device of claim 5, wherein the power switch circuit is configured to change the body voltage of the plurality of NMOS transistors from the first voltage to the second voltage by:
at a first time point, turning off the first switch in response to the first enable signal having a logic low level, turning on the second switch in response to the second enable signal having a logic high level, and turning off the third switch in response to the third enable signal having the logic low level,
wherein, in a period between the first time point and a second time point, the body voltage of the plurality of NMOS transistors decreases from the first voltage to the second voltage.

7. The memory device of claim 6, wherein the power switch circuit is configured to change the body voltage of the plurality of NMOS transistors from the second voltage to the first voltage by:
at a third time point, turning off the first switch in response to the first enable signal having the logic low level, turning off the second switch in response to the second enable signal having the logic low level, and turning on the third switch in response to the third enable signal having the logic high level; and
at a fourth time point, turning on the first switch in response to the first enable signal having the logic high level, turning off the second switch in response to the second enable signal having the logic low level, and turning off the third switch in response to the third enable signal having the logic low level,
wherein, in a period between the third time point and the fourth time point, the body voltage of the plurality of NMOS transistors increases from the second voltage to a voltage higher than the first voltage, and
wherein in a period between the fourth time point and a fifth time point, the body voltage of the plurality of NMOS transistors decreases from the voltage higher than the first voltage to the first voltage.

8. The memory device of claim 7, wherein the period between the third time point and the fourth time point is shorter than the period between the first time point and the second time point.

9. The memory device of claim 1, wherein the power switch circuit is configured to dynamically control the body voltage of the plurality of PMOS transistors by providing the first voltage having a first voltage level higher than a boost voltage, and the second voltage having a second voltage level higher than the first voltage.

10. A method of operating a memory device comprising a bit line sense amplifier and a power switch circuit, the method comprising the bit line sense amplifier:
performing an active operation;
performing a leakage current reduction operation; and
performing a precharge operation,
wherein the bit line sense amplifier comprises a plurality of NMOS transistors and a plurality of PMOS transistors, and
wherein the performing the leakage current reduction operation comprises the power switch circuit reducing a leakage current in the bit line sense amplifier by dynamically controlling one of a body voltage of the plurality of NMOS transistors and a body voltage of the plurality of PMOS transistors.

11. The method of claim 10, wherein the reducing the leakage current comprises the power switch circuit changing the body voltage of the plurality of NMOS transistors from a first voltage to a second voltage.

12. The method of claim 11, wherein the performing the leakage current reduction operation comprises the power switch circuit dynamically controlling the body voltage of the plurality of NMOS transistors by providing the first voltage having a first voltage level lower than a ground voltage, and the second voltage having a second voltage level lower than the first voltage.

13. The method of claim 12, wherein the performing the precharge operation comprises the power switch circuit changing the body voltage of the plurality of NMOS transistors from the second voltage to the first voltage.

14. The method of claim 13, wherein the changing the body voltage of the plurality of NMOS transistors from the second voltage to the first voltage comprises:
changing the body voltage of the plurality of NMOS transistors from the second voltage to a third voltage; and
changing the body voltage of the plurality of NMOS transistors from the third voltage to the first voltage,
wherein the third voltage has a third voltage level equal to the ground voltage, or lower than the ground voltage and higher than the first voltage.

15. The method of claim 14, wherein
the memory device further comprises a sub word line driver,
the bit line sense amplifier, the power switch circuit, and the sub word line driver are included in a peripheral circuit layer, and
the power switch circuit is included in a conjunction region between the bit line sense amplifier and the sub word line driver.

16. The method of claim 10, wherein the power switch circuit comprises a first switch, a second switch and a third switch, and wherein the power switch circuit:
provides a first voltage to a body node of the plurality of NMOS transistors through the first switch in response to a first enable signal;
provides a second voltage to the body node of the plurality of NMOS transistors through the second switch in response to a second enable signal; and
provides a third voltage to the body node of the plurality of NMOS transistors through the third switch in response to a third enable signal,
wherein the first voltage has a first voltage level lower than the third voltage, and the second voltage has a second voltage level lower than the first voltage.

17. The method of claim 16, wherein the performing the leakage current reduction operation comprises turning on the second switch, and turning off the first switch and the third switch.

18. The method of claim 16, wherein the performing the precharge operation comprises:
turning on the third switch, and turning off the first switch and the second switch; and
subsequently turning on the first switch, and turning off the second switch and the third switch.

19. A memory system comprising:
a memory controller comprising a power switch control circuit; and
a memory device comprising a power switch circuit and a bit line sense amplifier,
wherein the bit line sense amplifier comprises a plurality of NMOS transistors and a plurality of PMOS transistors, and
wherein the power switch circuit is configured to reduce a leakage current in the bit line sense amplifier by dynamically controlling one of a body voltage of the plurality of NMOS transistors and a body voltage of the plurality of PMOS transistors based on a plurality of enable signals received from the power switch control circuit.

20. The memory system of claim 19, wherein the power switch circuit is configured to dynamically control the body voltage of the plurality of NMOS transistors by:
changing the body voltage of the plurality of NMOS transistors from a first voltage to a second voltage, after the bit line sense amplifier performs an active operation; and
changing the body voltage of the plurality of NMOS transistors from the second voltage to a third voltage, and then changing the body voltage of the plurality of NMOS transistors from the third voltage to the first voltage, while the bit line sense amplifier performs a precharge operation,
wherein
the first voltage has a first voltage level lower than a ground voltage,
the second voltage has a second voltage level lower than the first voltage, and
the third voltage has a third voltage level equal to the ground voltage, or lower than the ground voltage and higher than the first voltage.
